(19) United States
(12) Patent Application Publication
(10) Pub. No.: US 2026/0318962 A1
(43) Pub. Date: Oct. 15, 2026

(54) Current Sense Apparatus and Control Method

(71) Applicant: Diodes Incorporated, Plano, TX (US)

(72) Inventors: Feng-Jung Huang, Taoyuan City (TW); Ko-Yen Lee, Taoyuan City (TW)

(21) Appl. No.: 19/183,917

(22) Filed: Apr. 20, 2025

Related U.S. Application Data
(63) Continuation of application No. PCT/US2025/024814, filed on Apr. 15, 2025.

(51) Int. Cl. G01R 19/25; G01R 19/00; H03K 3/017; H03K 17/56

(52) U.S. Cl. CPC G01R 19/25; G01R 19/0038; H03K 3/017; H03K 17/56; H03K 2217/0063; H03K 2217/0072

(57) ABSTRACT

An apparatus includes a current gain stage configured to receive two voltage signals and generate a current sense signal proportional to a current flowing through a power switch in a power converter, a current sense correction circuit configured to receive the current sense signal, a voltage across an inductor of the power converter, and a compensation signal, and generate a current sense correction factor, and a PWM comparator configured to receive the compensation signal and a corrected current sense signal, and generate a PWM signal, wherein the corrected current sense signal is obtained by adjusting the current sense signal based on the current sense correction factor.

### CROSS-REFERENCE TO RELATED APPLICATIONS

This application is a continuation of International Application No. PCT/US2025/024814, filed Apr. 15, 2025, the entire disclosure of which is incorporated herein by reference.

### TECHNICAL FIELD

The present disclosure relates generally to the field of power converters, and in particular embodiments, to techniques and mechanisms for accurately sensing a current flowing through a power converter.

### BACKGROUND

As technology continues to advance, the demand for efficient and reliable power converters has increased across various applications, including automotive, computing, and industrial power systems. Accurate current sensing in these converters is essential for ensuring optimal performance, safety, and efficiency.

Traditional current sensing techniques often utilize series resistors to measure current flow. While effective, these resistors introduce additional power losses and can occupy significant space, particularly in high-power applications. To overcome these limitations, designers have explored alternative methods, such as using the drain-to-source voltage of Metal-Oxide-Semiconductor Field-Effect Transistors (MOSFETs) to estimate the current flowing through the switch.

This approach relies on the drain-source on-resistance, where the current is inferred by measuring the drain-to-source voltage. However, a major challenge arises due to the temperature dependence of drain-source on-resistance. As the operating temperature fluctuates, drain-source on-resistance can vary significantly, leading to substantial inaccuracies in current measurement.

Changes in MOSFET temperature further impact its on-resistance, causing large deviations in the converter's calculations of both inductor current and load current. These deviations introduce significant challenges in achieving precise control over the power conversion process. Due to these deviations, the power converter requires a larger tolerance in overcurrent protection, which can compromise system efficiency and increase design complexity. Furthermore, deviations in current sensing necessitate a larger operating range to ensure that the power converter operates normally under conditions of current sensing inaccuracies. These requirements add complexity to the control circuitry and can impact overall system performance.

Another known method for current sensing involves using a current mirror to measure the current flowing through the power switch. This technique is relatively straightforward to implement in integrated switch power converters, where both the power switch and sensing circuit are on the same die. However, its applicability becomes more challenging in systems using external power switches.

To enable current mirroring for an external power switch, a specialized current mirror circuit can be designed. However, this approach increases system cost, as it typically requires non-standard power switches that support current mirroring functionality, making it less practical for cost-sensitive applications.

Various techniques have been proposed to address temperature-induced variations in drain-source on-resistance. However, existing methods struggle to provide accurate current sensing in high-power applications where the power switches and the controller are implemented on separate semiconductor dies. Therefore, there is a need for a current sensing apparatus that effectively compensates for temperature variations while maintaining simplicity and efficiency. The present disclosure addresses this need.

### SUMMARY

Technical advantages are generally achieved, by embodiments of this disclosure which describe a current sense apparatus for accurately sensing a current flowing through a power converter under various temperature conditions.

In accordance with an embodiment, an apparatus comprises a current gain stage configured to receive two voltage signals and generate a current sense signal proportional to a current flowing through a power switch in a power converter, a current sense correction circuit configured to receive the current sense signal, a voltage across an inductor of the power converter, and a compensation signal, and generate a current sense correction factor, and a pulse width modulation (PWM) comparator configured to receive the compensation signal and a corrected current sense signal, and generate a PWM signal, wherein the corrected current sense signal is obtained by adjusting the current sense signal based on the current sense correction factor.

Optionally, in the preceding aspect, the power converter is a buck converter comprising a high-side switch and a low-side switch connected in series between an input voltage bus and ground, an inductor connected between a common node of the high-side switch and the low-side switch, and an output voltage bus, and an output capacitor connected between the output voltage bus and ground.

Optionally, in any of the preceding aspects, the apparatus further comprises an error amplifier configured to generate the compensation signal, wherein the error amplifier, the current gain stage, the current sense correction circuit and the PWM comparator form a controller, and wherein the controller and the high-side switch of the buck converter are on two different semiconductor dies.

Optionally, in any of the preceding aspects, the two voltage signals comprise a first voltage signal sensed at a drain of the high-side switch and a second voltage signal sensed at a source of the high-side switch when the high-side switch is in an on state, and the current sense correction factor is inversely proportional to an increase in an on resistance of the high-side switch under different temperature conditions.

Optionally, in any of the preceding aspects, the current sense correction circuit comprises a first comparator configured to generate a first logic signal by comparing the compensation signal with the current sense signal, a second comparator configured to generate a second logic signal by comparing the current sense signal with the compensation signal reduced by a predetermined offset, a logic gate configured to generate a time difference signal by performing an AND logic operation on the first logic signal and the second logic signal, and a current sense correction factor generation circuit configured to generate the current sense correction factor by multiplying a predetermined coefficient, a voltage difference between a voltage on the input voltage bus and a voltage on the output voltage bus, and the time difference signal.

Optionally, in any of the preceding aspects, the current sense correction factor generation circuit comprises a first voltage-to-current converter and a second voltage-to-current converter connected in series between a bias voltage and ground, and wherein the first voltage-to-current converter is configured to receive the voltage on the input voltage bus, and the second voltage-to-current converter is configured to receive the voltage on the output voltage bus, a first resistor connected between a common node of the first voltage-to-current converter and the second voltage-to-current converter, and ground, and wherein a voltage across the first resistor is proportional to the voltage difference between the voltage on the input voltage bus and the voltage on the output voltage bus, a second resistor connected between the common node of the first voltage-to-current converter and the second voltage-to-current converter, and an input of a buffer, a switch connected between the input of the buffer and ground, and wherein the time difference signal is applied to a gate of the switch through an inverter, the buffer configured to generate an output signal equal to a product of the time difference signal and the voltage across the first resistor, a filter configured to receive an output signal of the buffer and generate a dc signal corresponding to a mean value of the output signal of the buffer, and a gain stage configured to receive an output signal of the filter and generate the current sense correction factor equal to a product of the predetermined coefficient and the output signal of the filter.

Optionally, in any of the preceding aspects, the corrected current sense signal is generated by multiplying the current sense signal with the current sense correction factor.

Optionally, in any of the preceding aspects, the corrected current sense signal is generated by adjusting a gain of the current gain stage based on the current sense correction factor.

Optionally, in any of the preceding aspects, one additional current gain stage configured to receive two voltage signals, wherein the corrected current sense signal is generated by adjusting a gain of the one additional current gain stage based on the current sense correction factor, and the current gain stage is configured to generate the current sense signal fed into the current sense correction circuit.

Optionally, in any of the preceding aspects, the power converter is a boost converter comprising an inductor and a low-side switch connected in series between an input voltage bus and ground, a high-side switch connected between a common node of the inductor and the low-side switch, and an output voltage bus, and an output capacitor connected between the output voltage bus and ground.

Optionally, in any of the preceding aspects, the current sense correction circuit comprises a first comparator configured to generate a first logic signal by comparing the compensation signal with the current sense signal, a second comparator configured to generate a second logic signal by comparing the current sense signal with the compensation signal reduced by a predetermined offset, a logic gate configured to generate a time difference by performing an AND logic operation on the first logic signal and the second logic signal, and a current sense correction factor generation circuit configured to calculate the current sense correction factor by multiplying a predetermined coefficient, a voltage on the input voltage bus, and the time difference.

In accordance with another embodiment, a method comprises generating a first logic signal by comparing a compensation signal with a current sense signal proportional to a current flowing through a power switch in a power converter, generating a second logic signal by comparing the current sense signal with the compensation signal reduced by a predetermined offset, generating a time difference by performing an AND logic operation on the first logic signal and the second logic signal, and generating a current sense correction factor by multiplying a predetermined coefficient, a voltage across an inductor of the power converter and the time difference.

Optionally, in the preceding aspect, the method further comprises generating, by a current gain stage, the current sense signal, wherein the current gain stage is configured to receive two voltage signals sensed at two terminals of the power switch, respectively, generating a corrected current sense signal by adjusting the current sense signal based on the current sense correction factor, and generating a PWM signal based on a comparison between the corrected current sense signal and the compensation signal.

Optionally, in any of the preceding aspects, the corrected current sense signal is generated by multiplying the current sense signal with the current sense correction factor, and the current sense correction factor is inversely proportional to an increase in an on resistance of the power switch under different temperature conditions.

Optionally, in any of the preceding aspects, the corrected current sense signal is generated by adjusting a gain of the current gain stage based on the current sense correction factor, and the current sense correction factor is inversely proportional to an increase in an on resistance of the power switch under different temperature conditions.

Optionally, in any of the preceding aspects, the power converter is a buck converter comprising a high-side switch and a low-side switch connected in series between an input voltage bus and ground, and an inductor connected between a common node of the high-side switch and the low-side switch, and an output voltage bus, and the two voltage signals comprise a first voltage signal sensed at a drain of the high-side switch and a second voltage signal sensed at a source of the high-side switch when the high-side switch is in an on state.

Optionally, in any of the preceding aspects, the power converter is a boost converter comprising an inductor and a low-side switch connected in series between an input voltage bus and ground, and a high-side switch connected between a common node of the inductor and the low-side switch, and an output voltage bus, and the two voltage signals comprise a first voltage signal sensed at a drain of the low-side switch and a second voltage signal sensed at a source of the low-side switch when the low-side switch is in an on state.

In accordance with yet another embodiment, a system comprises a power converter connected between an input voltage bus and an output voltage bus, and a controller electrically coupled to the power converter, wherein the controller comprises: a current gain stage configured to receive two voltage signals and generate a current sense signal proportional to a current flowing through a power switch in the power converter, a current sense correction circuit configured to receive the current sense signal, a voltage across an inductor of the power converter, and a compensation signal, and generate a current sense correction factor, and a PWM comparator configured to receive the compensation signal and a corrected current sense signal, and generate a PWM signal, wherein the corrected current sense signal is obtained by adjusting the current sense signal based on the current sense correction factor.

Optionally, in the preceding aspect, the power converter comprises a high-side switch and the low-side switch connected in series between the input voltage bus and ground, an inductor connected between a common node of the high-side switch and the low-side switch, and the output voltage bus, and an output capacitor connected between the output voltage bus and ground.

Optionally, in any of the preceding aspects, the current sense correction circuit comprises a first comparator configured to generate a first logic signal by comparing the compensation signal with the current sense signal, a second comparator configured to generate a second logic signal by comparing the current sense signal with the compensation signal reduced by a predetermined offset, a logic gate configured to generate a time difference by performing an AND logic operation on the first logic signal and the second logic signal, and a current sense correction factor generation circuit configured to calculate the current sense correction factor by multiplying a predetermined coefficient, a voltage difference between a voltage on the input voltage bus and a voltage on the output voltage bus, and the time difference.

Features described in the context of one embodiment may be used in combination with other embodiments. For example, each of the optional features described above in the context of the apparatus may be used in combination with the system. Each of the optional features described above in the context of the method may be used in combination with the system. Each of the optional features described above in the context of the apparatus may be used in combination with the method.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a block diagram of a power conversion system in accordance with various embodiments of the present disclosure;

FIG. 2 illustrates a block diagram of the controller shown in FIG. 1 in accordance with various embodiments of the present disclosure;

FIG. 3 illustrates various signals associated with the power converter and the controller shown in FIG. 1 in accordance with various embodiments of the present disclosure;

FIG. 4 illustrates a schematic diagram of the current sense correction circuit shown in FIG. 2 in accordance with various embodiments of the present disclosure;

FIG. 5 illustrates various signals associated with the current sense correction circuit shown in FIG. 4 in accordance with various embodiments of the present disclosure;

FIG. 6 illustrates a block diagram of the current sense correction factor generation circuit shown in FIG. 4 in accordance with various embodiments of the present disclosure;

FIG. 7 illustrates a schematic diagram of a first implementation of the power conversion system shown in FIG. 1 in accordance with various embodiments of the present disclosure;

FIG. 8 illustrates a schematic diagram of a second implementation of the power conversion system shown in FIG. 1 in accordance with various embodiments of the present disclosure;

FIG. 9 illustrates a schematic diagram of a third implementation of the power conversion system shown in FIG. 1 in accordance with various embodiments of the present disclosure;

FIG. 10 illustrates a schematic diagram of a fourth implementation of the power conversion system shown in FIG. 1 in accordance with various embodiments of the present disclosure; and

FIG. 11 illustrates a flow chart of a method for controlling the power conversion system shown in FIG. 1 in accordance with various embodiments of the present disclosure.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Further, one or more features from one or more of the following described embodiments may be combined to create alternative embodiments not explicitly described, and features suitable for such combinations are understood to be within the scope of this disclosure. It is therefore intended that the appended claims encompass any such modifications or embodiments.

The present disclosure will be described with respect to embodiments in a specific context, namely a current sense apparatus for accurately sensing a current flowing through a step-down power converter under various temperature conditions. The disclosure may also be applied, however, to a variety of power converters. Hereinafter, various embodiments will be explained in detail with reference to the accompanying drawings.

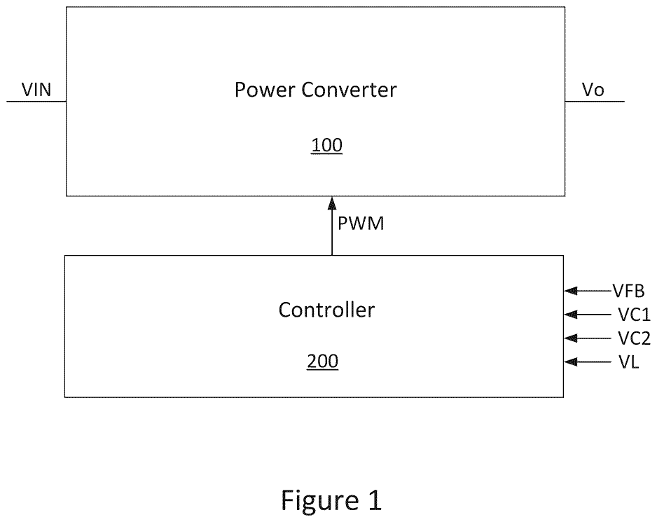

FIG. 1 illustrates a block diagram of a power conversion system in accordance with various embodiments of the present disclosure. The power conversion system comprises a power converter 100 and a controller 200. As shown in FIG. 1, the power converter 100 is connected between an input voltage bus VIN and an output voltage bus Vo. A load (not shown) is coupled to the output voltage bus Vo. In some embodiments, the load may be a processor (e.g., a central processing unit).

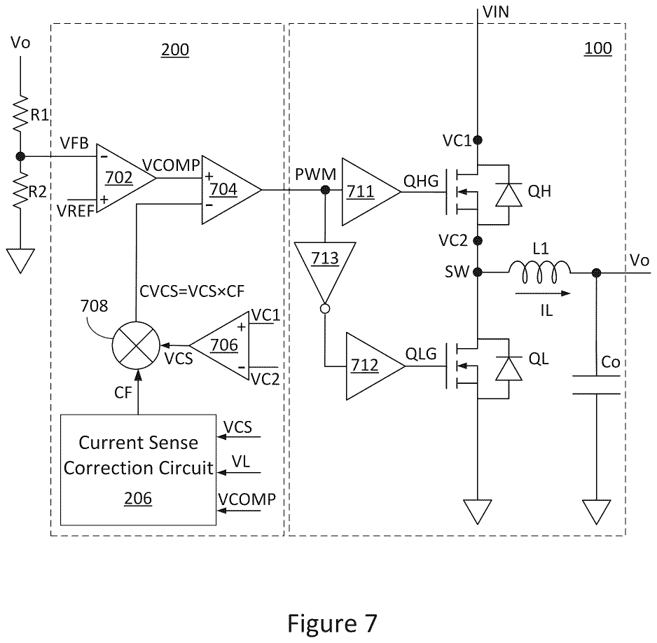

In some embodiments, the power converter 100 is implemented as a step-down power converter. The step-down power converter is formed by two power switches and an output filter. The two power switches include a high-side power switch and a low-side power switch connected in series between the input voltage bus VIN and ground. The high-side power switch and the low-side power switch are controlled to regulate the output voltage of the step-down power converter. The power converter 100 also includes a gate driver circuitry that controls the high-side and low-side power switches, optimizing the switching operation for speed and efficiency. The power converter 100 may further comprise other key components such as current sensing, temperature sensing and the like. The detailed structure of the step-down power converter will be described below with respect to FIGS. 7-9.

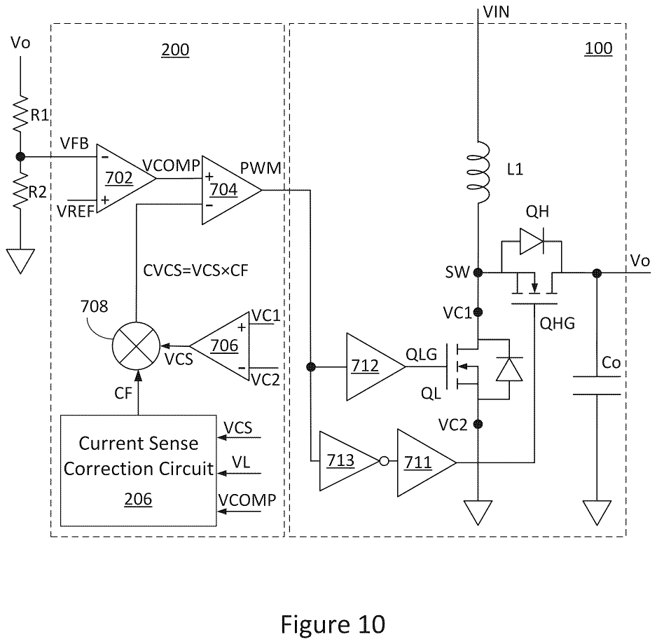

In alternative embodiments, the power converter 100 is implemented as a step-up power converter. The step-up power converter is formed by an inductor, two power switches and an output capacitor. The inductor and a low-side power switch are connected in series between the input voltage bus VIN and ground. A high-side power switch is connected between a common node of the inductor and the low-side power switch, and the output voltage bus Vo. The high-side power switch and the low-side power switch are controlled to regulate the output voltage of the step-up power converter. The detailed structure of the step-up power converter will be described below with respect to FIG. 10.

Furthermore, the power converter 100 may be implemented as any suitable power conversion topologies such as a flyback converter, a push-pull converter, an inductor-inductor-capacitor (LLC) converter, a switched capacitor converter, a hybrid switched capacitor converter, a full bridge power converter, a half bridge power converter, a buck-boost converter, and any combinations thereof and the like.

As shown in FIG. 1, the controller 200 is electrically coupled to the power converter 100. In particular, the controller 200 is configured to receive a feedback signal VFB proportional to the output voltage Vo, a first voltage signal VC1, a second voltage signal VC2 and a signal VL, and generate a PWM signal to control the power converter 100. In some embodiments, the power converter 100 is a buck converter. The first voltage signal VC1 and the second voltage signal VC2 are sensed at a drain and a source of the high-side switch of the buck converter, respectively when the high-side switch is in an on state. VL is equal to a voltage difference between VIN and Vo. In alternative embodiments, the power converter 100 is a boost converter. The first voltage signal VC1 and the second voltage signal VC2 are sensed at a drain and a source of the low-side switch of the boost converter, respectively when the low-side switch is in an on state. VL is equal to the input voltage VIN.

In operation, the controller 200 determines a current sense correction factor based on VC1, VC2, and VL to adjust the current sense signal, compensating for temperature effects. This results in a corrected current sense signal. The corrected current sense signal and a compensation signal are used to generate a PWM signal to regulate Vo.

In some embodiments, the controller 200 may be a system controller or a system control apparatus. The controller 200 may be implemented as a microprocessor, a digital signal processor and the like.

In some embodiments, the controller 200 and the power converter 100 are implemented on separate semiconductor dies. Specifically, the high-side and low-side switches of the power converter 100 are discrete components and are not integrated with the controller 200.

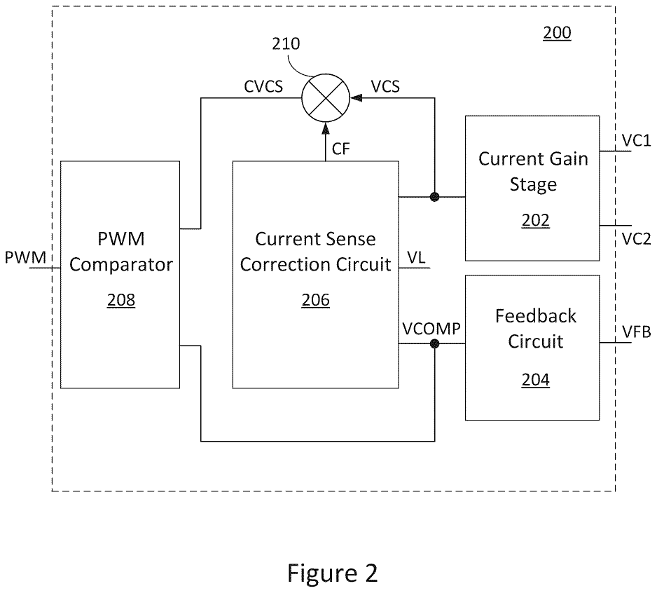

FIG. 2 illustrates a block diagram of the controller shown in FIG. 1 in accordance with various embodiments of the present disclosure. The controller 200 comprises a current gain stage 202, a feedback circuit 204, a current sense correction circuit 206, a PWM comparator 208 and a coefficient multiplier 210.

As shown in FIG. 2, the current gain stage 202 is configured to receive two voltage signals VC1 and VC2. The current gain stage 202 is configured to generate a current sense signal VCS proportional to a current flowing through the power converter 100. When the power converter 100 is implemented as a buck converter, VCS is proportional to a current flowing through the high-side switch of the buck converter. Alternatively, when the power converter 100 is implemented as a boost converter, VCS is proportional to a current flowing through the low-side switch of the boost converter.

The feedback circuit 204 comprises an error amplifier. The error amplifier is configured to receive a feedback signal VFB proportional to Vo and a predetermined reference (VREF). The error amplifier generates a compensation signal VCOMP based on the difference between the feedback signal VFB and the predetermined reference. In some embodiments, a compensation network is connected to the output of the error amplifier to ensure loop stability by shaping the frequency response of the voltage control loop.

The current sense correction circuit 206 is configured to receive VCOMP, VL and VCS as shown in FIG. 2. Based on the received signals, the current sense correction circuit 206 is configured to generate a current sense correction factor CF fed into the coefficient multiplier 210. In some embodiments, the current sense correction factor CF is inversely proportional to an increase in an on resistance of the high-side switch under different temperature conditions. As a result, the current sense correction factor CF can be used to compensate for temperature-induced variations in the current sense signal VCS.

The coefficient multiplier 210 is configured to generate a corrected current sense signal CVCS through multiplying the current sense signal VCS with the current sense correction factor CF. The PWM comparator 208 is configured to receive the compensation signal VCOMP and the corrected current sense signal CVCS, and generate a PWM signal based on the comparation between the compensation signal VCOMP and the corrected current sense signal CVCS.

The block diagram of the controller 200 presented in this disclosure illustrates only the components relevant to the innovative aspects of the invention. It is understood that, depending on design requirements, the controller 200 may include additional functional blocks necessary for implementation, such as protection circuits, or other control features, which are not explicitly shown but may be incorporated as needed.

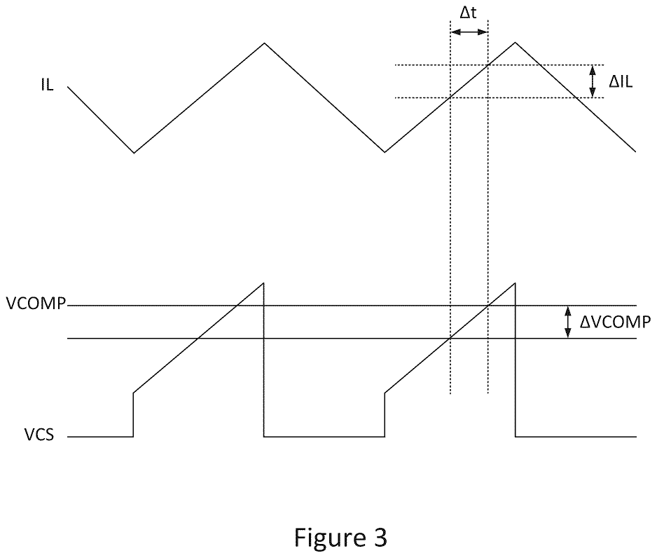

FIG. 3 illustrates various signals associated with the power converter and the controller shown in FIG. 1 in accordance with various embodiments of the present disclosure. The horizontal axis represents intervals of time. There are two rows. The first row represents the current flowing through the inductor of the power converter. The second row includes the compensation signal VCOMP and the current sense signal VCS.

As shown in FIG. 3, there is a voltage variation of VCOMP. The volage variation of VCOMP is denoted as ΔVCOMP. In some embodiments, ΔVCOMP is a predetermined voltage offset. As shown in FIG. 3, a voltage variation of VCS corresponds to the predetermined voltage offset ΔVCOMP. The voltage variation of VCS is denoted as ΔVCS. As shown in FIG. 3, ΔVCOMP and ΔVCS satisfy the following equation:

ΔVCOMP=ΔVCS (1)

The on-resistance of the high-side switch is denoted as RDS_{ON}. The gain of the current gain stage 202 is denoted as G_{CS}. As shown in FIG. 3, the variation of the inductor current IL corresponding to ΔVCS is denoted as ΔIL. ΔVCS can be expressed by the following equation:

ΔVCS=ΔIL×RDS_{ON}×G_{CS} (2)

When the power converter is implemented as a buck converter, VL is the voltage across the inductor when the high-side switch is turned on. ΔIL can be expressed by the following equation:

$$Δ IL = \frac{V L}{L} \times Δ t \qquad ( 3 )$$

In Equation (3), L represents the inductance of the power converter's inductor. As shown in FIG. 3, Δt denotes the time duration corresponding to ΔVCOMP.

Based on Equations (1)-(3), ΔVCOMP can be expressed by the following equation:

$$ΔV COMP = \frac{V L}{L} \times Δ t \times {RDS}_{ON} \times {G}_{CS} \qquad ( 4 )$$

As indicated by Equation (4), in a fixed-amplitude window of VCOMP, any change in RDS_{ON} results in an inverse variation of VL×Δt, assuming that L and G_{CS} remain constant in the power conversion system.

According to Equation (4), a current sense correction factor can be generated, which is proportional to the variation of VL×Δt and inversely proportional to RDS_{ON}. This current sense correction factor CF is a function of VL and Δt within a fixed-amplitude VCOMP window. CF can be expressed by the following equation:

CF=f(VL,Δt) (5)

In operation, the current sense correction factor CF can be multiplied with the original VCS signal. Since CF is inversely proportional to the variation of RDS_{ON}, the impact of RDS_{ON} changes on VCS can be eliminated, thereby obtaining a correct current sense signal CVCS, which can be expressed by the following equation:

CVCS=CF×VCS (6)

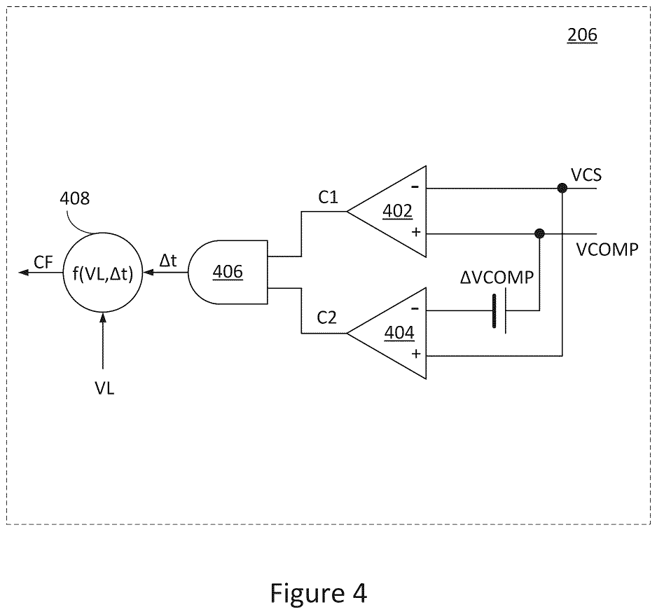

FIG. 4 illustrates a schematic diagram of the current sense correction circuit shown in FIG. 2 in accordance with various embodiments of the present disclosure. The current sense correction circuit 206 comprises a first comparator 402, a second comparator 404, a logic gate 406 and a current sense correction factor generation circuit 408. In some embodiments, the logic gate 406 is implemented as an AND gate as shown in FIG. 4.

As shown in FIG. 4, an inverting input of the first comparator 402 is configured to receive the current sense signal VCS. A non-inverting of the first comparator 402 is configured to receive VCOMP. The first comparator 402 is configured to generate a first logic signal C1 by comparing the compensation signal VCOMP with the current sense signal VCS.

An inverting input of the second comparator 404 is configured to receive VCOMP reduced by a predetermined offset ΔVCOMP. In some embodiments, ΔVCOMP is equal to 300 millivolts. A non-inverting of the second comparator 404 is configured to receive the current sense signal VCS. The second comparator 404 is configured to generate a second logic signal C2 by comparing the current sense signal VCS with the compensation signal VCOMP reduced by the predetermined offset ΔVCOMP.

The logic gate 406 is configured to generate a time difference signal Δt by performing an AND logic operation on the first logic signal C1 and the second logic signal C2. The current sense correction factor generation circuit 408 is configured to generate the current sense correction factor CF by multiplying a predetermined coefficient K, VL and the time difference signal Δt. In some embodiments, K is in a range from about 10 to about 20.

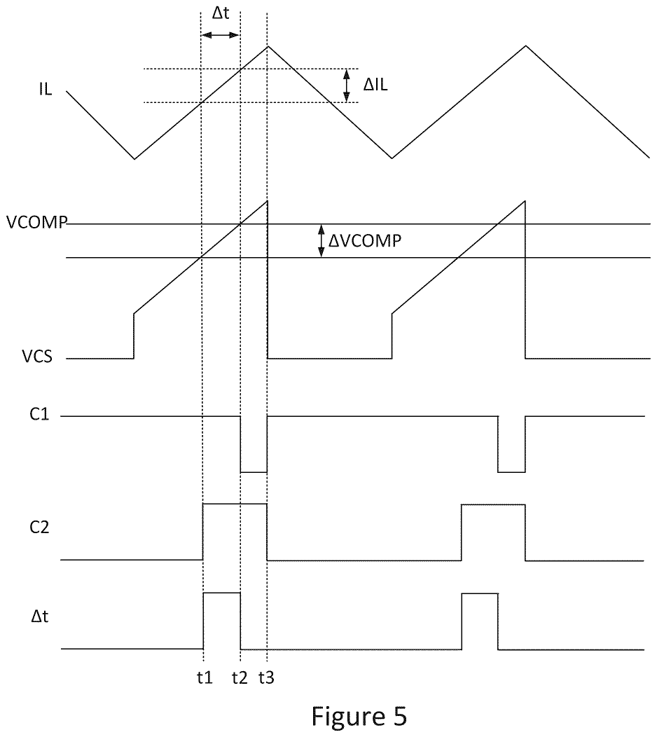

FIG. 5 illustrates various signals associated with the current sense correction circuit shown in FIG. 4 in accordance with various embodiments of the present disclosure. The first row represents the current flowing through the inductor in the power converter. The second row includes the compensation signal VCOMP, the predetermined offset ΔVCOMP and the current sense signal VCS. The third row represents the first logic signal C1. The fourth row represents the second logic signal C2. The fifth row represents the time difference signal Δt.

Prior to t1, the compensation signal VCOMP is greater than the current sense signal VCS, and (VCOMP-ΔVCOMP) is greater than the current sense signal VCS. Referring back to FIG. 4, according to the configuration of the first comparator 402, the first control signal C1 has a logic high state. According to the configuration of the second comparator 404, the second control signal C2 has a logic low state.

At t1, the current sense signal VCS exceeds (VCOMP-ΔVCOMP). As a result, the second control signal C2 changes from a logic low state to a logic high state. At t2, the current sense signal VCS exceeds the compensation signal VCOMP. As a result, the first control signal C1 changes from a logic high state to a logic low state. The logic state of the second control signal C2 remains the same from t2 to t3.

At t3, the current sense signal VCS drops below (VCOMP-ΔVCOMP). In response to this change, the first control signal C1 changes from a logic low state to a logic high state. The second control signal C2 changes from a logic high state to a logic low state. After t3, the process described above is repeated.

Referring back to FIG. 4, the time difference signal Δt is generated by performing an AND logic operation on the first logic signal C1 and the second logic signal C2. As shown in FIG. 5, from t1 to t2, both the first control signal C1 and the second control signal C2 have a logic high state. By performing the AND logic operation on the first logic signal C1 and the second logic signal C2, the time difference signal Δt has a logic high state from t1 to t2 as shown in FIG. 5.

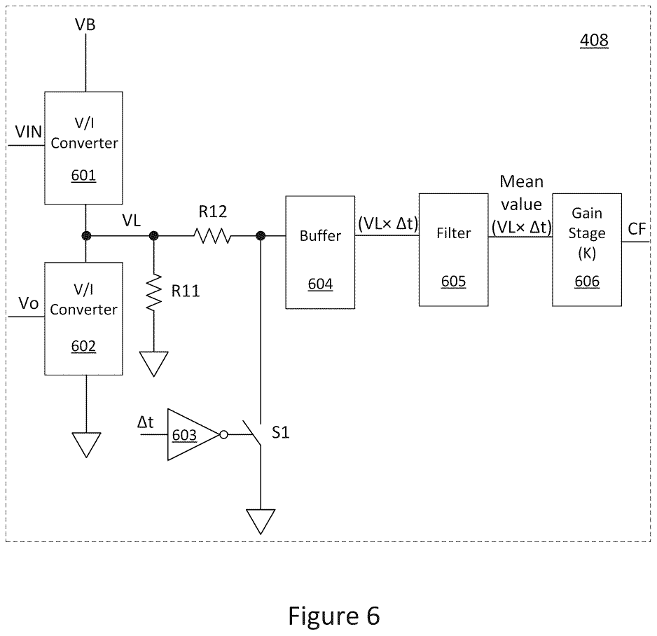

FIG. 6 illustrates a block diagram of the current sense correction factor generation circuit shown in FIG. 4 in accordance with various embodiments of the present disclosure. The current sense correction factor generation circuit 408 comprises a first voltage-to-current converter 601, a second voltage-to-current converter 602, a first resistor R11, a second resistor R12, a switch S1, an inverter 603, a buffer 604, a filter 605 and a gain stage 606.

The first voltage-to-current converter 601 and a second voltage-to-current converter 602 are implemented as suitable integrated circuits such as transconductance amplifiers and the like. As shown in FIG. 6, the first voltage-to-current converter 601 and the second voltage-to-current converter 602 are connected in series between a bias voltage VB and ground. The first resistor R11 is connected between a common node of the first voltage-to-current converter 601 and the second voltage-to-current converter 602, and ground.

The first voltage-to-current converter 601 is configured to receive the input voltage VIN. The second voltage-to-current converter 602 is configured to receive the output voltage Vo. The voltage difference of VIN and Vo is converted into a current flowing through the first resistor R11. VL is the voltage across the first resistor R11. VL is proportional to the voltage difference of VIN and Vo.

The time difference signal Δt is applied to the gate of the switch S1 through the inverter 603. When the time difference signal Δt has a logic high state, the switch S1 is turned off. VL is fed into the input of the buffer 604 through the second resistor R12. When the time difference signal Δt has a logic low state, the switch S1 is turned on. The input of the buffer 604 is grounded. As such, the signal fed into the buffer 604 is equal to VL×Δt.

In some embodiments, the buffer 604 is implemented as a unity-gain buffer, which is well known in the art. This unity-gain buffer is configured to provide high input impedance, low output impedance, and signal isolation without amplification. As shown in FIG. 6, the buffer 604 generates an output signal equal to the input signal (VL×Δt).

The filter 605 is implemented as any suitable low-pass filter such as a resistor-capacitor filter and the like. The filter 605 is configured to receive the output signal of the buffer 604 and generate a dc signal corresponding to a mean value of the output signal (VL×Δt) of the buffer 604. The gain stage 606 is configured to receive an output signal of the filter 605. In some embodiments, the gain of the gain stage 606 is equal to the predetermined coefficient K. The gain stage 606 generates the current sense correction factor CF equal to a product of the predetermined coefficient K and the output signal of the filter 605. In other words, CF is equal to K×VL×Δt.

FIG. 7 illustrates a schematic diagram of a first implementation of the power conversion system shown in FIG. 1 in accordance with various embodiments of the present disclosure. The power converter 100 is implemented as a step-down power converter. The step-down power converter comprises a high-side switch QH, a low-side switch QL, an output inductor L1 and an output capacitor Co. As shown in FIG. 7, the high-side switch QH and the low-side switch QL are connected in series between the input voltage bus VIN and ground. The output inductor L1 is connected between a common node (SW) of the high-side switch QH and the low-side switch QL, and the output voltage bus Vo. The current flowing through the inductor L1 is denoted as IL as shown in FIG. 7. The output capacitor Co is connected between the output voltage bus Vo and ground.

The power converter 100 further comprises a high-side driver 711, a low-side driver 712 and an inverter 713. The high-side driver 711 is configured to receive the PWM signal from the controller 200. Based on the received signal, the high-side driver 711 generates a high-side gate drive signal QHG applied to the gate of the high-side switch QH. The PWM signal passes through the inverter 713. The low-side driver 712 is configured to receive the output signal of the inverter 713. Based on the received signal, the low-side driver 712 generates a low-side gate drive signal QLG applied to the gate of the low-side switch QL.

The driver circuit shown in FIG. 7 is a simplified representation provided to illustrate the innovative aspects of the present disclosure. It should be understood that in practical implementations, the driver circuit may include additional functional blocks such as a dead time control circuit or other necessary circuitry to ensure proper operation.

The controller 200 comprises an error amplifier 702, a PWM comparator 704, a current sense correction circuit 206, a current gain stage 706 and a coefficient multiplier 708. A resistor divider formed by R1 and R2 is connected between Vo and ground.

In operation, an inverting input of the error amplifier 702 receives a feedback signal VFB obtained at a midpoint of the resistor divider. A non-inverting input of the error amplifier 702 receives a predetermined reference VREF. The error amplifier 702 generates a compensation signal VCOMP based on the comparison between the feedback signal VFB and the predetermined reference VREF. In some embodiments, a compensation network (not shown) is connected to the output of the error amplifier 702 to improve loop stability.

The current gain stage 706 is configured to receive two voltage signals VC1 and VC2. VC1 is obtained from the drain of the high-side switch QH. VC2 is obtained from the source of the high-side switch QH. The current gain stage 706 is configured to generate a current sense signal VCS proportional to a current flowing through the high-side switch QH.

The current sense correction circuit 206 is configured to receive the compensation signal VCOMP, VL and the current sense signal VCS as shown in FIG. 7. VL is equal to the voltage difference between VIN and Vo. Based on the received signals, the current sense correction circuit 206 is configured to generate a current sense correction factor CF fed into the coefficient multiplier 210.

In some embodiments, the current sense correction factor CF is inversely proportional to an increase in an on resistance of the high-side switch QH under different temperature conditions. As a result, the current sense correction factor CF can be used to compensate for temperature-induced variations in the current sense signal VCS.

The coefficient multiplier 708 is configured to generate a corrected current sense signal CVCS through multiplying the current sense signal VCS with the current sense correction factor CF. The PWM comparator 704 is configured to receive the compensation signal VCOMP and the corrected current sense signal CVCS, and generate a PWM signal based on the comparation between VCOMP and CVCS.

In accordance with an embodiment, the switches (e.g., switches QH and QL) may be metal oxide semiconductor field-effect transistor (MOSFET) devices. Alternatively, the switches can be any controllable switches such as insulated gate bipolar transistor (IGBT) devices, integrated gate commutated thyristor (IGCT) devices, gate turn-off thyristor (GTO) devices, silicon-controlled rectifier (SCR) devices, junction gate field-effect transistor (JFET) devices, MOS controlled thyristor (MCT) devices, gallium nitride (GaN)-based power devices, silicon carbide (SiC)-based power devices and the like.

It should be noted while FIG. 7 shows the switches QH and QL are implemented as single n-type transistors, a person skilled in the art would recognize there may be many variations, modifications and alternatives. For example, depending on different applications and design needs, the switches QH and QL may be implemented as p-type transistors. Furthermore, each switch shown in FIG. 7 may be implemented as a plurality of switches connected in parallel.

In the power converter shown in FIG. 7, the low-side switch QL is implemented using a power switch, such as a power MOSFET. However, a person of ordinary skill in the art would recognize that, depending on design requirements, the power switch may be replaced with a diode. This substitution is common in certain applications where simplicity, cost, or efficiency considerations favor the use of a diode instead of an actively controlled switch. For example, in applications where the conduction losses of a diode are acceptable, a Schottky or other suitable diode may be used in place of the low-side power switch.

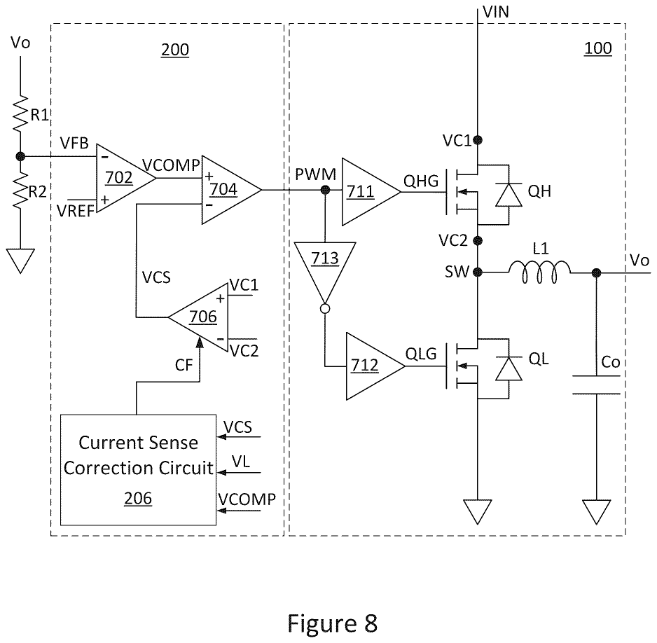

FIG. 8 illustrates a schematic diagram of a second implementation of the power conversion system shown in FIG. 1 in accordance with various embodiments of the present disclosure. The second implementation shown in FIG. 8 is similar to the first implementation shown in FIG. 7 except that the current sense correction factor CF is used to adjust the gain of the current gain stage 706. In some embodiments, the current gain stage 706 is implemented as an adjustable gain current sense amplifier. The current sense correction factor CF is fed into the current gain stage 706 to modify the gain, ensuring accurate current sensing under varying temperature conditions.

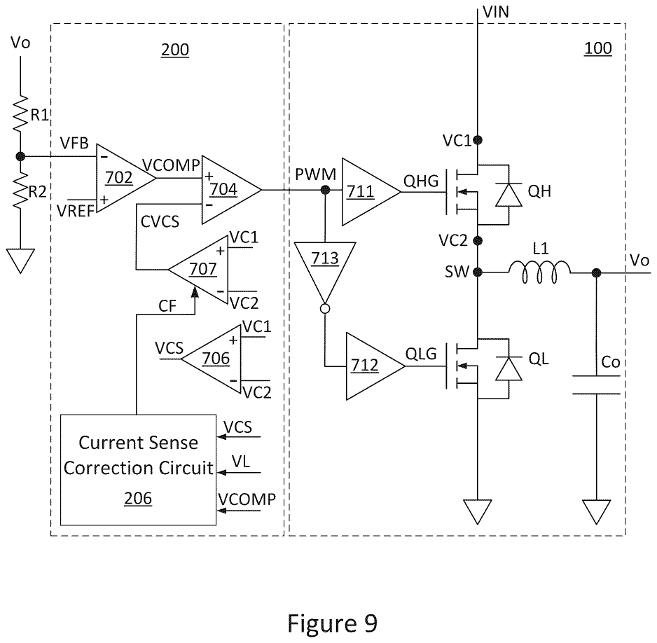

FIG. 9 illustrates a schematic diagram of a third implementation of the power conversion system shown in FIG. 1 in accordance with various embodiments of the present disclosure. The third implementation shown in FIG. 9 is similar to the first implementation shown in FIG. 7 except that one more current gain stage 707 is employed, and the current sense correction factor CF is used to adjust the gain of the current gain stage 707. In some embodiments, the current gain stage 706 is configured to generate the current sense signal VCS fed into the current sense correction circuit 206. The current gain stage 707 is implemented as an adjustable gain current sense amplifier. The current sense correction factor CF is fed into the current gain stage 707 to modify the gain, ensuring accurate current sensing under varying temperature conditions.

FIG. 10 illustrates a schematic diagram of a fourth implementation of the power conversion system shown in FIG. 1 in accordance with various embodiments of the present disclosure. The fourth implementation shown in FIG. 10 is similar to the first implementation shown in FIG. 7 except that the power converter is implemented as a boost converter.

As shown in FIG. 10, the boost converter comprises an inductor L1, a low-side switch QL, a high-side switch QH and an output capacitor Co. The inductor L1 and the low-side switch QL are connected in series between an input voltage bus VIN and ground. The high-side switch QH connected between a common node of the inductor L1 and the low-side switch QL, and an output voltage bus Vo. The output capacitor Co is connected between the output voltage bus Vo and ground.

The low-side driver 712 is configured to receive the PWM signal from the controller 200. Based on the received signal, the low-side driver 712 generates a low-side gate drive signal QLG applied to the gate of the low-side switch QL. The PWM signal passes through the inverter 713. The high-side driver 711 is configured to receive the output signal of the inverter 713. Based on the received signal, the high-side driver 711 generates a high-side gate drive signal QHG applied to the gate of the high-side switch QH.

The driver circuit shown in FIG. 10 is a simplified representation provided to illustrate the innovative aspects of the present disclosure. It should be understood that in practical implementations, the driver circuit may include additional functional blocks such as a dead time control circuit or other necessary circuitry to ensure proper operation.

The operating principle and structure of the controller 200 in FIG. 10 is similar to that shown in FIG. 7 except that VL is equal to the input voltage VIN.

In the power converter shown in FIG. 10, the high-side switch QH is implemented using a power switch. However, a person of ordinary skill in the art would recognize that, depending on design requirements, the power switch may be replaced with a diode. This substitution is common in certain applications where simplicity, cost, or efficiency considerations favor the use of a diode instead of an actively controlled switch. For example, in applications where the conduction losses of a diode are acceptable, a Schottky or other suitable diode may be used in place of the high-side power switch.

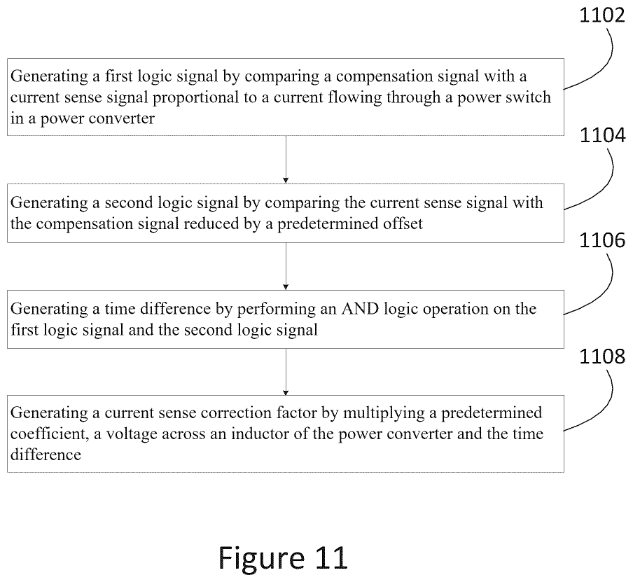

FIG. 11 illustrates a flow chart of a method for controlling the power conversion system shown in FIG. 1 in accordance with various embodiments of the present disclosure. This flowchart shown in FIG. 11 is merely an example, which should not unduly limit the scope of the claims. One of ordinary skill in the art would recognize many variations, alternatives, and modifications. For example, various steps illustrated in FIG. 11 may be added, removed, replaced, rearranged and repeated.

Referring to FIG. 1, a power converter is connected between an input voltage bus and an output voltage bus. A controller is electrically coupled to the power converter. Referring to FIG. 2, the controller comprises a feedback circuit, a current gain stage, a current sense correction circuit and a PWM comparator. The current gain stage is configured to receive two voltage signals and generate a current sense signal proportional to a current flowing through a power switch in the power converter. The current sense correction circuit is configured to receive the current sense signal, a voltage across an inductor of the power converter, and a compensation signal, and generate a current sense correction factor. The PWM comparator is configured to receive the compensation signal and a corrected current sense signal, and generate a PWM signal, wherein the corrected current sense signal is obtained by adjusting the current sense signal based on the current sense correction factor. The current sense correction factor is generated based on the following steps.

At step 1102, a first logic signal is generated by comparing a compensation signal with a current sense signal proportional to a current flowing through a power switch in a power converter.

At step 1104, a second logic signal is generated by comparing the current sense signal with the compensation signal reduced by a predetermined offset.

At step 1106, a time difference is generated by performing an AND logic operation on the first logic signal and the second logic signal.

At step 1108, a current sense correction factor is generated by multiplying a predetermined coefficient, a voltage across an inductor of the power converter and the time difference.

The method further comprises generating, by a current gain stage, the current sense signal, wherein the current gain stage is configured to receive two voltage signals sensed at two terminals of the power switch, respectively, generating a corrected current sense signal by adjusting the current sense signal based on the current sense correction factor, and generating a PWM signal based on a comparison between the corrected current sense signal and the compensation signal.

In some embodiments, the corrected current sense signal is generated by multiplying the current sense signal with the current sense correction factor, and the current sense correction factor is inversely proportional to an increase in an on resistance of the power switch under different temperature conditions.

In some embodiments, the corrected current sense signal is generated by adjusting a gain of the current gain stage based on the current sense correction factor, and the current sense correction factor is inversely proportional to an increase in an on resistance of the power switch under different temperature conditions.

In some embodiments, the power converter is a buck converter comprising a high-side switch and a low-side switch connected in series between an input voltage bus and ground, and an inductor connected between a common node of the high-side switch and the low-side switch, and an output voltage bus, and the two voltage signals comprise a first voltage signal sensed at a drain of the high-side switch and a second voltage signal sensed at a source of the high-side switch when the high-side switch is in an on state.

In some embodiments, the power converter is a boost converter comprising an inductor and a low-side switch connected in series between an input voltage bus and ground, and a high-side switch connected between a common node of the inductor and the low-side switch, and an output voltage bus, and the two voltage signals comprise a first voltage signal sensed at a drain of the low-side switch and a second voltage signal sensed at a source of the low-side switch when the low-side switch is in an on state.

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, which may perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed is:

1. An apparatus comprising:
a current gain stage configured to receive two voltage signals and generate a current sense signal proportional to a current flowing through a power switch in a power converter;
a current sense correction circuit configured to receive the current sense signal, a voltage across an inductor of the power converter, and a compensation signal, and generate a current sense correction factor; and
a pulse width modulation (PWM) comparator configured to receive the compensation signal and a corrected current sense signal, and generate a PWM signal, wherein the corrected current sense signal is obtained by adjusting the current sense signal based on the current sense correction factor.

2. The apparatus of claim 1, wherein the power converter is a buck converter comprising:
a high-side switch and a low-side switch connected in series between an input voltage bus and ground;
an inductor connected between a common node of the high-side switch and the low-side switch, and an output voltage bus; and
an output capacitor connected between the output voltage bus and ground.

3. The apparatus of claim 2, further comprising:
an error amplifier configured to generate the compensation signal, wherein the error amplifier, the current gain stage, the current sense correction circuit and the PWM comparator form a controller, and wherein the controller and the high-side switch of the buck converter are on two different semiconductor dies.

4. The apparatus of claim 2, wherein:
the two voltage signals comprise a first voltage signal sensed at a drain of the high-side switch and a second voltage signal sensed at a source of the high-side switch when the high-side switch is in an on state; and
the current sense correction factor is inversely proportional to an increase in an on resistance of the high-side switch under different temperature conditions.

5. The apparatus of claim 2, wherein the current sense correction circuit comprises:
a first comparator configured to generate a first logic signal by comparing the compensation signal with the current sense signal;
a second comparator configured to generate a second logic signal by comparing the current sense signal with the compensation signal reduced by a predetermined offset;
a logic gate configured to generate a time difference signal by performing an AND logic operation on the first logic signal and the second logic signal; and
a current sense correction factor generation circuit configured to generate the current sense correction factor by multiplying a predetermined coefficient, a voltage difference between a voltage on the input voltage bus and a voltage on the output voltage bus, and the time difference signal.

6. The apparatus of claim 5, wherein the current sense correction factor generation circuit comprises:
a first voltage-to-current converter and a second voltage-to-current converter connected in series between a bias voltage and ground, and wherein the first voltage-to-current converter is configured to receive the voltage on the input voltage bus, and the second voltage-to-current converter is configured to receive the voltage on the output voltage bus;
a first resistor connected between a common node of the first voltage-to-current converter and the second voltage-to-current converter, and ground, and wherein a voltage across the first resistor is proportional to the voltage difference between the voltage on the input voltage bus and the voltage on the output voltage bus;
a second resistor connected between the common node of the first voltage-to-current converter and the second voltage-to-current converter, and an input of a buffer;
a switch connected between the input of the buffer and ground, and wherein the time difference signal is applied to a gate of the switch through an inverter;
the buffer configured to generate an output signal equal to a product of the time difference signal and the voltage across the first resistor;
a filter configured to receive an output signal of the buffer and generate a dc signal corresponding to a mean value of the output signal of the buffer; and
a gain stage configured to receive an output signal of the filter and generate the current sense correction factor equal to a product of the predetermined coefficient and the output signal of the filter.

7. The apparatus of claim 1, wherein:
the corrected current sense signal is generated by multiplying the current sense signal with the current sense correction factor.

8. The apparatus of claim 1, wherein:
the corrected current sense signal is generated by adjusting a gain of the current gain stage based on the current sense correction factor.

9. The apparatus of claim 1, further comprising:
one additional current gain stage configured to receive two voltage signals, wherein:
the corrected current sense signal is generated by adjusting a gain of the one additional current gain stage based on the current sense correction factor; and
the current gain stage is configured to generate the current sense signal fed into the current sense correction circuit.

10. The apparatus of claim 1, wherein the power converter is a boost converter comprising:
an inductor and a low-side switch connected in series between an input voltage bus and ground;
a high-side switch connected between a common node of the inductor and the low-side switch, and an output voltage bus; and
an output capacitor connected between the output voltage bus and ground.

11. The apparatus of claim 10, wherein the current sense correction circuit comprises:
a first comparator configured to generate a first logic signal by comparing the compensation signal with the current sense signal;
a second comparator configured to generate a second logic signal by comparing the current sense signal with the compensation signal reduced by a predetermined offset;
a logic gate configured to generate a time difference by performing an AND logic operation on the first logic signal and the second logic signal; and
a current sense correction factor generation circuit configured to calculate the current sense correction factor by multiplying a predetermined coefficient, a voltage on the input voltage bus, and the time difference.

12. A method comprising:
generating a first logic signal by comparing a compensation signal with a current sense signal proportional to a current flowing through a power switch in a power converter;
generating a second logic signal by comparing the current sense signal with the compensation signal reduced by a predetermined offset;
generating a time difference by performing an AND logic operation on the first logic signal and the second logic signal; and
generating a current sense correction factor by multiplying a predetermined coefficient, a voltage across an inductor of the power converter and the time difference.

13. The method of claim 12, further comprising:
generating, by a current gain stage, the current sense signal, wherein the current gain stage is configured to receive two voltage signals sensed at two terminals of the power switch, respectively;
generating a corrected current sense signal by adjusting the current sense signal based on the current sense correction factor; and
generating a PWM signal based on a comparison between the corrected current sense signal and the compensation signal.

14. The method of claim 13, wherein:
the corrected current sense signal is generated by multiplying the current sense signal with the current sense correction factor; and
the current sense correction factor is inversely proportional to an increase in an on resistance of the power switch under different temperature conditions.

15. The method of claim 13, wherein:
the corrected current sense signal is generated by adjusting a gain of the current gain stage based on the current sense correction factor; and
the current sense correction factor is inversely proportional to an increase in an on resistance of the power switch under different temperature conditions.

16. The method of claim 13, wherein:
the power converter is a buck converter comprising a high-side switch and a low-side switch connected in series between an input voltage bus and ground, and an inductor connected between a common node of the high-side switch and the low-side switch, and an output voltage bus; and
the two voltage signals comprise a first voltage signal sensed at a drain of the high-side switch and a second voltage signal sensed at a source of the high-side switch when the high-side switch is in an on state.

17. The method of claim 13, wherein:
the power converter is a boost converter comprising an inductor and a low-side switch connected in series between an input voltage bus and ground, and a high-side switch connected between a common node of the inductor and the low-side switch, and an output voltage bus; and
the two voltage signals comprise a first voltage signal sensed at a drain of the low-side switch and a second voltage signal sensed at a source of the low-side switch when the low-side switch is in an on state.

18. A system comprising:
a power converter connected between an input voltage bus and an output voltage bus; and
a controller electrically coupled to the power converter, wherein the controller comprises:
a current gain stage configured to receive two voltage signals and generate a current sense signal proportional to a current flowing through a power switch in the power converter;
a current sense correction circuit configured to receive the current sense signal, a voltage across an inductor of the power converter, and a compensation signal, and generate a current sense correction factor; and
a PWM comparator configured to receive the compensation signal and a corrected current sense signal, and generate a PWM signal, wherein the corrected current sense signal is obtained by adjusting the current sense signal based on the current sense correction factor.

19. The system of claim 18, wherein the power converter comprises:
a high-side switch and the low-side switch connected in series between the input voltage bus and ground;
an inductor connected between a common node of the high-side switch and the low-side switch, and the output voltage bus; and
an output capacitor connected between the output voltage bus and ground.

20. The system of claim 18, wherein:
the current sense correction circuit comprises:
a first comparator configured to generate a first logic signal by comparing the compensation signal with the current sense signal;
a second comparator configured to generate a second logic signal by comparing the current sense signal with the compensation signal reduced by a predetermined offset;
a logic gate configured to generate a time difference by performing an AND logic operation on the first logic signal and the second logic signal; and
a current sense correction factor generation circuit configured to calculate the current sense correction factor by multiplying a predetermined coefficient, a voltage difference between a voltage on the input voltage bus and a voltage on the output voltage bus, and the time difference.
